(19) United States
(12) Patent Application Publication
(10) Pub. No.: US 2024/0002997 A1
(43) Pub. Date: Jan. 4, 2024

(54) SPUTTERING TARGET

(71) Applicant: NGK INSULATORS, LTD., Nagoya-shi (JP)

(72) Inventors: Kentaro NONAKA, Gifu-shi, Gifu (JP); Yoshinori ISODA, Nagoya-shi, Aichi (JP); Katsuhiro IMAI, Nagoya-shi, Aichi (JP)

(21) Appl. No.: 18/465,265

(22) Filed: Sep. 12, 2023

Related U.S. Application Data
(63) Continuation of application No. PCT/JP2022/001705, filed on Jan. 19, 2022.

(30) Foreign Application Priority Data
Mar. 30, 2021 (JP) 2021-057250

(51) Int. Cl. C23C 14/34

(52) U.S. Cl. CPC C23C 14/3407

(57) ABSTRACT

A sputtering target includes a gallium nitride-based crystalline body composed of a plurality of gallium nitride-based monocrystalline grains whose c-axes are orientated in a direction normal to a predetermined surface. The gallium nitride-based crystalline body has a total oxygen concentration of 150 mass ppm or lower, and the gallium nitride-based monocrystalline grains have oxygen concentrations of 2×10¹⁷ cm⁻³ or higher measured by dynamic SIMS method.

### CROSS-REFERENCE TO RELATED APPLICATIONS

This application is a continuation application of PCT/JP2022/001705, filed Jan. 19, 2022, which claims priority to Japanese Application No. JP2021-057250 filed on Mar. 30, 2021, the entire contents all of which are incorporated hereby by reference.

### TECHNICAL FIELD

The present invention is related to a sputtering target composed of a gallium nitride-based crystalline body.

### BACKGROUND ART

Sputtering method is listed as a technique for forming a gallium nitride thin film. According to the sputtering method, it has been studied to use a sputtering target composed of, for example, gallium nitride as a raw material. As the sputtering target, a target produced by sintering gallium nitride powder (for example, patent document 1) and a target composed of a polycrystalline body produced by hydride vapor phase deposition method or the like (for example, patent document 2 and non-patent document 1) have been proposed.

### PRIOR TECHNICAL DOCUMENTS

### Non-Patent Documents

(Non-patent document 1)
“Synthesis of dense polycrystalline GaN of high purity by the chemical vapor reaction process” (Journal of Crystal Growth Volume 286, Issue 1, 1 Jan. 2006, Pages 50-54)

### PATENT DOCUMENTS

(Patent document 1) WO 2016/158651 A1
(Patent document 2) Japanese patent publication No. 2018-119171 A

### SUMMARY OF THE INVENTION

In the case that a sintered body composed of gallium nitride powder was formed to provide a sputtering target, the surface of the gallium nitride powder as a raw material is susceptible to oxidation so that oxygen is discharged from the target at the time of initiation of sputtering and gallium oxide is easily generated. Further, as spaces are present between the sintered grains, it is difficult to increase the density of the target resulting in a problem.

In the case that a sputtering target is composed of a polycrystalline body formed by hydride vapor phase deposition method or flux method, the target having a high density can be easily obtained. However, forming the gallium nitride polycrystalline body, for example as described in patent document 2, it is considered the methods of using a substrate of a different kind whose crystalline structure or lattice constant is substantially different from gallium nitride as an underlying substrate or of film-forming embodiment in which a low temperature buffer layer is not used. In this case, impurities such as oxygen are susceptible to be incorporated so that it is difficult to obtain a low oxygen concentration required for a sputtering target.

On the other hand, according to non-patent document 1, it is reported that CVPR method, which is a vapor phase deposition method applying a chloride raw material (NH₄Cl), is used to synthesize a polycrystalline gallium nitride having a high density at a relatively low oxygen concentration. However, as the thus obtained crystal is not orientated in a specific crystalline orientation and the quality is not uniform, it is considered that erosion (the target is unevenly evaporated) occurs during the sputtering and the life of the target becomes short.

The present inventors have tried to use a gallium nitride single crystal substrate as a sputtering target. However, there are problems in the single crystal substrate that fracture may easily occur during the sputtering and the film-forming rate of the sputtering is very low.

An object of the present invention is to provide a gallium nitride-based sputtering target having a low oxygen concentration and hard to break during sputtering.

The present invention provides a sputtering target comprising a gallium nitride-based crystalline body comprising a plurality of gallium nitride-based monocrystalline grains whose c-axes are orientated in a direction normal to a predetermined surface,

wherein said gallium nitride-based crystalline body has a total oxygen concentration of 150 mass ppm or lower, and

wherein said gallium nitride-based monocrystalline grains have oxygen concentrations measured by dynamic SIMS method of 2×10¹⁷ cm⁻³ or higher.

The present inventors applied, as a sputtering target, a gallium nitride-based polycrystalline body composed of a plurality of gallium nitride-based monocrystalline grains orientated in c-axis. It is thereby possible that uniform quality can be easily obtained, erosion (phenomenon that the target is unevenly evaporated) during the sputtering is suppressed and the life of the target is made longer. In addition to this, the total oxygen concentration of the gallium nitride-based crystalline body is further lowered, so that the oxygen concentration of the gallium nitride-based crystal film obtained by sputtering can be made lower and stabilized. The present inventors have tried to further reduce the oxygen concentration of the gallium nitride-based crystalline body for this purpose.

However, surprisingly, when the oxygen concentration of the gallium nitride-based crystalline body is made low, it is proved that fracture of the sputtering target may occur during the sputtering. Although the cause is not clear, it is considered that as the oxygen concentration of the gallium nitride-based crystalline body is considerably reduced, the regularity of arrangement of the monocrystalline grains constituting the gallium nitride-based crystalline body is improved and resembles monocrystalline structure, so that the fracture tends to occur.

Specifically, as the total oxygen concentration of the gallium nitride-based crystalline body is made 150 mass ppm or lower, the oxygen concentration of the thus obtained gallium nitride-based crystal film obtained by sputtering can be lowered and the quality can be stabilized. At the same time, it is found that, as the oxygen concentrations of the gallium nitride-based monocrystalline grains constituting the gallium nitride-based crystalline body measured by dynamic SIMS method is made 2×10¹⁷ cm⁻³ or higher, the fracture of the sputtering target during the sputtering can be suppressed. The present invention is thus made.

### BRIEF DESCRIPTION OF THE DRAWINGS

FIG. 1 is a diagram schematically showing a sputtering target 1.

FIG. 2 shows an X-ray diffraction chart obtained in the example.

### MODES FOR CARRYING OUT THE INVENTION

The present invention will be described further in detail below, appropriately referring to drawings.

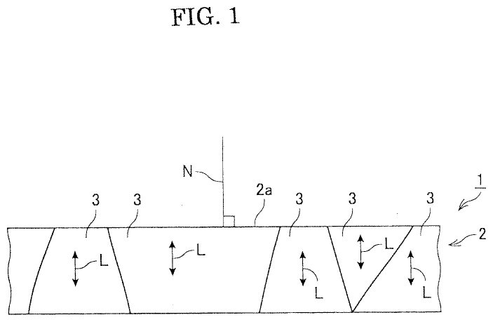

As schematically shown in FIG. 1, a sputtering target 1 of the present invention is composed of a gallium nitride-based crystalline body 2 composed of a plurality of gallium nitride-based monocrystalline grains 3 whose c-axes are orientated in a direction N substantially normal to a predetermined surface 2a.

That is, the gallium nitride-based crystalline body 2 is a polycrystalline body composed of a plurality of gallium nitride-based monocrystalline grains 3. Thus, the predetermined surface 2a of the gallium nitride-based crystalline body is applied for the sputtering. Then, the crystalline orientation L of each gallium nitride-based monocrystalline grain 3 is substantially c-axis orientation viewed in the direction N normal to the predetermined surface.

According to a preferred embodiment, the half value width of (002) plane reflection of an X-ray rocking curve of the gallium nitride-based crystalline body is 1000 seconds or lower. As the gallium nitride-based crystalline body having such high c-axis orientation is applied, the quality of the thus obtained gallium nitride-based crystal is further improved. On the viewpoint, the half value width of the (002) plane reflection of X-ray rocking curve of the gallium nitride-based crystalline body may more preferably be 800 seconds or lower.

The gallium nitride-based crystalline body 2 described above can be observed as an aggregation of monocrystalline grains of pillar-like structure, in which a single crystal is observed viewed in the normal direction N and grain boundaries are observed in a plane cut in a direction of a horizontal plane. Here, (pillar-like structure) not only means typical elongate pillar shape but also means to include various shapes such as a horizontally elongate shape, trapezoid shape and shape which trapezoid shape is positioned upside down. Further, as described above, it is not necessary to be pillar shaped structure in a strict meaning, as far as the gallium nitride-based crystalline body has the structure in which it has crystalline orientation aligned in the normal direction or the direction conforming to the normal direction at some degree.

The total oxygen concentration of the gallium nitride-based crystalline body constituting the sputtering target of the present invention is 150 mass ppm or lower, and the oxygen concentrations of the gallium nitride-based monocrystalline grains measured by dynamic SIMS method is 2×10¹⁷ cm⁻³ or higher.

Here, the total oxygen concentration of the gallium nitride-based crystalline body is measured by elemental analysis and can specifically be measured by oxygen-nitrogen simultaneous analyzer (for example, “EMGA-650W” manufactured by HORIBA corporation). Thus, the total oxygen concentration of the gallium nitride-based crystalline body is made 150 mass ppm or lower and may preferably be 50 mass ppm or lower.

As the total oxygen concentration of the gallium nitride-based crystalline body is made lower, the oxygen concentration of the gallium nitride-based crystalline film obtained by sputtering is lowered and stabilized. However, as the present inventors actually researched, in the case that the oxygen concentration of the gallium nitride-based crystalline body is too low, cracks may be easily generated in the sputtering target during the sputtering. On the viewpoint of suppressing the cracks in the target during the sputtering, it is found that a minute amount of oxygen is necessary to be contained.

However, according to the method of measuring the total oxygen concentration of the gallium nitride-based crystalline body by the oxygen-nitrogen simultaneous analyzer, it is found that the oxygen concentration is near the measurement limit and that an oxygen concentration required for suppressing the cracks in the target cannot be clarified. Thus, it is researched the method of quantifying the oxygen concentrations of the respective gallium nitride-based monocrystalline grains by dynamic SIMS method. This is the procedure of quantifying the oxygen concentration of a fine region on the predetermined surface of the gallium nitride-based crystalline body. As a result, it is found that the cracks of the target during the sputtering can be considerably suppressed by making the measured value of the oxygen concentrations of the gallium nitride-based monocrystalline grain by dynamic SIMS method 2×10¹⁷ cm⁻³ or higher.

Further, the measured value of the oxygen concentrations of the gallium nitride-based monocrystalline grain may preferably be made 3×10¹⁹/cm³ or lower, more preferably be made 1×10¹⁹/cm³ or lower and particularly preferably be made 5×10¹⁸/cm³ or lower.

The oxygen concentrations of the gallium nitride-based monocrystalline grains are measured by dynamic SIMS method as follows.

That is, the oxygen concentration is measured in a square-shaped visual field of 200 μm and 200 μm on the predetermined surface of gallium nitride-based crystalline body by dynamic SIMS. The measurement is performed on nine visual fields and the average value is calculated.

The gallium nitride-based crystalline body is represented by AlₓGa₁₋ₓN or InₓGa₁₋ₓN, and in this case, x may preferably be 0.5 or lower and more preferably be 0.2 or lower. x may be 0.

According to a preferred embodiment, the measured value of the relative density of the sputtering target by Archimedean method is 98.0% or higher, preferably 99.0% or higher and more preferably 99.5% or higher. According to such gallium nitride-based crystalline body of a high density, the erosion or oxidation is suppressed during the sputtering.

According to a preferred embodiment, the thickness of the sputtering target is 1 mm or larger. The thickness may more preferably be 2 mm or larger and most preferably be 4 mm or larger. Further, the thickness may preferably be 8 mm or smaller on a practical viewpoint.

Further, according to a preferred embodiment, the diameter of the sputtering target is 50 mm or larger. The diameter may preferably be 75 mm or larger and more preferably be 100 mm or larger. Further, the diameter may preferably be 160 mm or smaller on a practical viewpoint.

According to a preferred embodiment, the sputtering target does not have translucent property. That is, the sputtering target is colored. The cause of the coloration is considered to be optical absorption due to defects such as nitrogen deficiency. As it has such defects, the film-formation rate during the sputtering is improved.

According to a preferred embodiment, the measured value of the carbon concentrations of the gallium nitride-based monocrystalline grains by dynamic SIMS method is 1×10¹⁶ cm⁻³ or lower. It is thereby possible to further improve the quality of the gallium nitride-based crystal generated by the sputtering.

According to a preferred embodiment, the measured value of the germanium concentrations of the gallium nitride-based monocrystalline grains by dynamic SIMS method is 1×10¹⁸ cm⁻³ or higher. It is thereby possible to obtain the sputtering target having a reduced resistivity of the target material and conductivity. On the viewpoint, the measured value of the germanium concentrations of the gallium nitride-based monocrystalline grains by dynamic SIMS method may preferably be 5×10¹⁸ cm⁻³ or higher.

It is preferred to polish the predetermined surface of the gallium nitride-based crystalline body forming the sputtering target, on the viewpoint of preventing erosion. On the viewpoint, the arithmetic average roughness Ra of the predetermined surface of the gallium nitride-based crystalline body may preferably be 0.1 μm or lower.

An n-type dopant and/or p-type dopant may be doped into the gallium nitride-based crystalline body forming the sputtering target, and such dopant may be zinc, calcium, iron, beryllium, magnesium, strontium, cadmium, scandium, silicon, germanium or tin.

As the sputtering system applying the sputtering target of the present invention, DC sputtering method, RF sputtering method, AC sputtering method, DC magnetron sputtering method, RF magnetron sputtering method, ion beam sputtering method or the like may be appropriately selected.

The pressure of gas during the sputtering may preferably be made 0.05 to 7.0 Pa. Further, the gas for the sputtering may preferably be mixed gases of argon (Ar) gas and nitrogen (N₂) gas.

Further, the temperature during the sputtering may preferably be made 100 to 1000° C.

### EXAMPLES

### Inventive Example 1

(Production of Sputtering Target)

Gallium nitride crystalline body was produced, basically according to the method described in WO 2017-145803A1.

Specifically, a seed crystal film having a thickness of 2 μm and composed of gallium nitride was film-formed by MOCVD method, on an orientated polycrystalline alumina sintered body having a diameter of p 4 inches, to obtain a seed crystal substrate.

The seed crystal substrate was placed in an alumina crucible in a globe box filled with nitrogen atmosphere. Then, gallium metal and sodium metal were filled in the crucible so that Ga/Ga+Na (mol %) becomes 30 mol %, and an alumina plate was placed thereon as a lid. The crucible was contained in an inner container made of stainless steel, the inner container was contained in a pressure resistant container made of stainless steel capable of containing it, and the pressure resistant container was closed with a container lid equipped with a nitrogen introduction pipe. The pressure resistant container was mounted on a rotatable table provided on a heating part of a crystal producing system which was baked in vacuum in advance, and a lid was placed on the pressure resistant container for the sealing.

Then, the inside of the pressure resistant container was drawn into vacuum by means of a vacuum pump to 0.1 Pa or less. Then, while an upper heater, intermediate heater and lower heater were adjusted so that the temperature in a heating space was adjusted at 880° C., nitrogen gas was introduced to a pressure of 4.0 MPa through a nitrogen gas bombe and the outer container was rotated around a central axis at 20 rpm in clockwise and anti-clockwise motions at a predetermined interval. The acceleration time was made 15 seconds, retention time was made 600 seconds, deceleration time was 15 seconds and stop time was made 1 second. The state was maintained for 10 hours. Thereafter, the upper heater, intermediate heater and lower heater were adjusted so that the temperature of the heating space was made 790° C., and the rotational rate of the pressure resistant container was made 20 rpm in clockwise and anti-clockwise motions at a predetermined interval. The acceleration time was made 8 seconds, retention time was made 300 seconds, deceleration time was made 8 seconds and stop time was made 0.5 seconds. It was then held at this state for 200 hours to grow gallium nitride crystal. However, according to the present example, oxygen sources in the respective containers were excluded as possible, the growth temperature of the gallium nitride crystal was lowered to, for example, 800° C. or lower and the direction of rotation of the pressure-resistant container was periodically changed, so that the measured values of the total oxygen concentration of the gallium nitride-based crystalline body and oxygen concentrations of the gallium nitride monocrystalline grains were adjusted.

After it was then spontaneously cooled to room temperature and the pressure was reduced to atmospheric pressure, the lid of the pressure-resistant container was opened and the crucible was taken out of the inside. Sodium metal solidified in the crucible was removed and an ingot of the gallium nitride crystalline body free from cracks separated from the seed crystal substrate was collected.

The surface of the ingot was subjected to polishing to obtain a sputtering target having a diameter of 4 inches and thickness of 2 mm and composed of gallium nitride crystalline body. However, as the respective elemental analysis measurements are destructive inspection, a plurality of samples for the respective elemental concentration measurements and sputtering experiment were separated and prepared.

(Measurement of Concentrations of Respective Elements)

The thus produced sputtering target was cut out into pieces each of 20 mm square and subjected to measurement of the oxygen concentration by oxygen-nitrogen simultaneous analyzing system (EMGA-650W manufactured by HORIBA corporation), and a value of 150 mass ppm was obtained.

Further, as to a predetermined surface of the thus produced sputtering target, the oxygen concentrations in a region of 200 μm and 200 μm were measured at nine positions by dynamic SIMS method and the average value was calculated to obtain a value of 2.0×10¹⁷/cm³.

The total oxygen concentration measured by the oxygen-nitrogen simultaneous analysis and oxygen concentrations measured by dynamic SIMS are different form each other, because the crystal growth was performed at a temperature lower than the conventional temperature and the growth rate of facet growth with a larger amount of incorporated oxygen was improved to generate a difference of oxygen concentrations between the c-plane growth parts and facet plane growth parts.

Further, the carbon concentration measured by dynamic SIMS were proved to be 5×10¹⁵/cm³ or lower at all the nine measurement points.

Further, the germanium concentrations measured by dynamic SIMS were proved to be 2×10¹⁶/cm³ or lower at all the nine measurement points.

(XRC-FWHM Measurement)

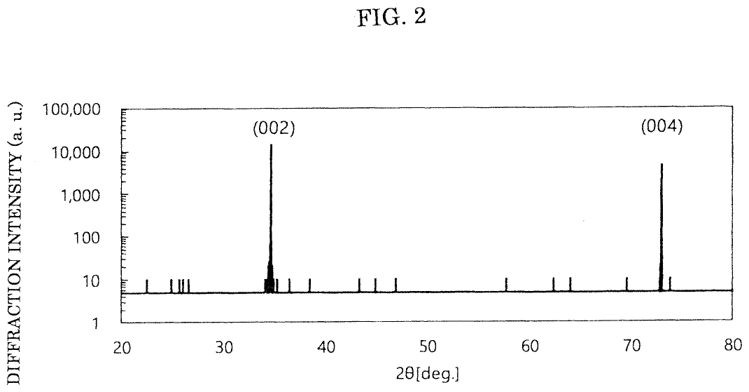

As to the predetermined surface of the thus produced sputtering target, an XRD system (D8-DISCOVER manufactured by Bruker-AXS Corporation) was used and CuKα ray was applied to perform the measurement of 2θ-ω. Ge (022) asymmetrical reflection monochromator and a slit of w 1 mm and h 10 mm were used as the incident side optical system. The measurement was performed under the conditions that the range of 2θ was made 20° or higher and 80° or lower, and the measurement distance was made 0.01° and measurement time period was made 0.5 seconds. FIG. 2 is a graph showing the results of the 2θ-ω measurement.

As shown in FIG. 2, only diffraction peaks of (002) and (004) planes equivalent with c plane were confirmed. Further, the (002) reflection of X-ray rocking curve was measured and the half value width was calculated to obtain a value of 684 arcsec. As can be seen from the above results, the gallium nitride-based monocrystalline grains were proved to be strongly oriented in c-axis.

(Sputtering Test)

The sputtering target was bonded with a heated copper plate (backing plate) through indium metal to obtain a bonded body.

The bonded body was used, an RF sputtering system was used under the conditions of chamber atmosphere of 20 sccm of Ar and 100 sccm of N₂ and of a chamber pressure of 0.25 Pa, a 2-inch sapphire substrate was used as a substrate, the distance between the target and substrate was made 150 mm and the temperature of the substrate was set at 500° C., to perform the film-formation of gallium nitride crystal by sputtering. Further, the appearance of the sputtering target after the sputtering was inspected.

As a result, after the sputtering treatment, as the sapphire substrate was taken out, gallium nitride crystal film having a thickness of 1 μm was formed uniformly. As the gallium nitride film was subjected to SIMS analysis, the oxygen concentrations were proved to be 1×10¹⁷/cm³ or lower.

Further, abnormality such as brokage or cracks was not observed on the appearance of the sputtering target after the film-formation and sputtering.

FIG. 1 summarizes the results of measurement obtained in the inventive example 1.

### Comparative Example 1

(Production of Sputtering Target)

A seed crystal film having a thickness of 2 μm and composed of gallium nitride was film-formed by MOCVD method, on an orientated polycrystalline alumina sintered body having a diameter of p 4 inches, to obtain a seed crystal substrate.

The seed crystal substrate was placed in an alumina crucible in a globe box filled with nitrogen atmosphere. Then, gallium metal and sodium metal were filled in the crucible so that Ga/Ga+Na (mol %) becomes 30 mol %, and an alumina plate was placed thereon as a lid.

The crucible was contained in an inner container made of stainless steel, the inner container was contained in a pressure resistant container made of stainless steel capable of containing it, and the pressure resistant container was closed with a container lid equipped with a nitrogen introduction pipe. The pressure resistant container was mounted on a rotatable table provided on a heating part of a crystal producing system which was baked in vacuum in advance, and a lid was placed on the pressure resistant container for the sealing.

Then, the inside of the pressure resistant container was drawn into vacuum by means of a vacuum pump to 0.1 Pa or less. Then, while an upper heater, intermediate heater and lower heater were adjusted so that the temperature in a heating space was adjusted at 880° C., nitrogen gas was introduced to a pressure of 4.0 MPa through a nitrogen gas bombe and the outer container was rotated around a central axis at 20 rpm in clockwise and anti-clockwise motions at a predetermined interval. The acceleration time was made 15 seconds, retention time was made 600 seconds, deceleration time was 15 seconds and stop time was made 1 second. It was then held at this state for 200 hours. After it was then spontaneously cooled to room temperature and the pressure was reduced to atmospheric pressure, the lid of the pressure-resistant container was opened and the crucible was taken out from the inside. Although the ingot of gallium nitride crystalline body was separated from the seed crystal substrate, cracks were generated.

### Comparative Example 2

As GaN crystal was grown under the same conditions as the comparative example 1 except that the retention time was made 60 hours, it could be produced gallium nitride crystalline body ingot separated from the seed crystal substrate and free from cracks. A predetermined surface of the ingot of the gallium nitride crystalline body was subjected to polishing to obtain a sputtering target having a thickness of 0.8 mm.

As the thus produced sputtering target was cut out into pieces each of 20 mm square, the surface was polished and then subjected to measurement of the total oxygen concentration by oxygen-nitrogen simultaneous analyzing system (EMGA-650W manufactured by HORIBA corporation), it was proved to be below the lower limit (10 mass ppm) of the measurement.

Further, the oxygen concentrations of the thus obtained sputtering target were measured at the nine positions by dynamic SIMS method and the respective values were proved to be 3×10¹⁶/cm³ or lower.

Further, as the X-ray diffraction measurement was performed as the inventive example 1, only diffraction peaks of (002) plane and (004) plane were confirmed. Further, as the (002) reflection of the X-ray rocking curve was measured and the half value width was calculated, a value of 83 arcsec was obtained.

(Sputtering Experiment)

As sputtering was performed according to the same procedure as the inventive example 1, cracks were generated in the target during the sputtering and the film formation by the sputtering was terminated.

### Inventive Examples 2 to 5

The respective gallium nitride crystalline body ingots and sputtering targets of the inventive examples 2 to 5 were produced as shown in table 1, according to the same procedure as that of the inventive example 1. However, in the inventive example 1, the temperature in the heating space during the retention time of 200 hours was adjusted to control the oxygen concentration.

Further, in the inventive example 5, gallium metal and sodium metal were filled in the alumina crucible together with germanium tetrachloride added in the ratio that Ge/Ga+Na+Ge (mol %) was 0.6 mol %.

As to the sputtering targets of the respective inventive examples, the respective concentrations of elements were measured, X-ray diffraction measurement was performed and sputtering experiment was performed, according to the same procedure as that of the inventive example 1. The results were shown in table 1.

As a result, as the sapphire substrate was taken out after the sputtering treatment, gallium nitride crystal film having a thickness of 1 μm was uniformly formed. As the gallium nitride crystal film was subjected to SIMS analysis, the oxygen concentrations were proved to be 2×10¹⁷/cm³ or higher.

Further, abnormality such as fracture or cracks was not observed on the appearance of the target after the film formation and sputtering.

### Comparative Example 3

The gallium nitride crystalline body ingot and sputtering target were produced as the comparative example 2. However, in the comparative example 2, gallium metal and sodium metal were filled in the alumina crucible together with germanium tetrachloride added in the ratio that Ge/Ga+Na+Ge (mol %) was 0.6 mol %.

As to the sputtering target of the comparative example 3, the respective concentrations of elements were measured, X-ray diffraction measurement was performed and sputtering experiment was performed, according to the same procedure as that of the inventive example 1. The results were shown in table 1.

Further, as sputtering was performed according to the same procedure as that of the inventive example 1, cracks were generated in the target during the sputtering and the film-formation by the sputtering was terminated.

### Comparative Example 4

A gallium nitride sintered body was produced according to the description of (0067) of WO 2016-158651 A1 and applied as a sputtering target.

That is, 200 g of gallium nitride powder having an average grain diameter of 1 μm was sintered by a mold of graphite with p 120 mm and by hot pressing under the conditions of 110° C. and a surface pressure of 200 kgf/c m² over 3 hours.

The thus obtained sintered body was subjected to polishing to obtain a sputtering target having a thickness of 2.0 mm.

The total oxygen concentration of the sputtering target of the present example was 800 mass ppm. Further, non-oriented sate was observed by X-ray diffraction result.

Further, the sputtering experiment was performed as the inventive example 1. As a result, as the sapphire substrate was taken out after the sputtering treatment, gallium nitride crystal film having a thickness of 1 μm was uniformly formed. As the gallium nitride crystal film was subjected to SIMS analysis, the oxygen concentrations were proved to be 2×10²⁰/cm³ or higher.

Further, abnormality such as fracture or cracks was not observed on the appearance of the target after the film formation and sputtering.

TABLE 1

Production of target

| | | | D-SIMS | D-SIMS | D-SIMS | |
|---|---|---|---|---|---|---|
| | | Total Oxygen | oxygen | carbon | germanium | XRC |
| | Density | concentration | concentration | concentration | concentration | (002) |
| Examples | (%) | (mass ppm) | (/cm³) | (/cm³) | (/cm³) | seconds |
| Inv. Ex. 1 | 98.8 | 150 | 2 × 10¹⁷ | 5 × 10¹⁵ | 2 × 10¹⁶or | 684 |
| | | | | or less | less | |
| Inv. Ex. 2 | 99.5 | 130 | 3 × 10¹⁷ | 5 × 10¹⁵ | 2 × 10¹⁶or | 649 |
| | | | | or less | less | |
| Inv. Ex. 3 | 99.2 | 150 | 8 × 10¹⁷ | 5 × 10¹⁵or | 2 × 10¹⁶or | 820 |
| | | | | less | less | |
| Inv. Ex. 4 | 98.3 | 150 | 5 × 10¹⁸ | 5 × 10¹⁵or | 2 × 10¹⁶or | 710 |
| | | | | less | less | |
| Inv. Ex. 5 | 99.2 | 150 | 2 × 10¹⁷ | 5 × 10¹⁵ | 6 × 10¹⁸ | 723 |
| | | | | or less | | |

| | |
|---|---|
| Com. Ex. 1 | Not evaluated as cracks were generated at the time of production of ingot |

| | | | | | | |
|---|---|---|---|---|---|---|
| Com. Ex. 2 | 99.7 | Less than | 3 × 10¹⁶ | 5 × 10¹⁵ | 2 × 10¹⁶or | 83 |
| | | lower limit | or less | or less | less | |
| Com. Ex. 3 | 99.7 | Less than | 3 × 10¹⁶or | 5 × 10¹⁵ | 6 × 10¹⁸ | 71 |
| | | lower limit | less | or less | | |
| Com. Ex. 4 | 66.3 | 800 | — | — | — | Non- |
| | | | | | | oriented |

Sputtering experiment

| | Cracks after | Oxygen concentration |
|---|---|---|
| Examples | sputtering | of GaN film (/cm³) |
| Inv. Ex. 1 | None | 1 × 10¹⁷or less |
| Inv. Ex. 2 | None | 1 × 10¹⁷or less |
| Inv. Ex. 3 | None | 1 × 10¹⁷or less |
| Inv. Ex. 4 | None | 1 × 10¹⁷or less |
| Inv. Ex. 5 | None | 1 × 10¹⁷or less |

| | |
|---|---|
| Com. Ex. 1 | — |

| | | |
|---|---|---|
| Com. Ex. 2 | Observed | — |
| Com. Ex. 3 | Observed | — |
| Com. Ex. 4 | None | 2 × 10²⁰ |

1. A sputtering target comprising a gallium nitride-based crystalline body comprising a plurality of gallium nitride-based monocrystalline grains whose c-axes are orientated in a direction normal to a predetermined surface,
wherein said gallium nitride-based crystalline body has a total oxygen concentration of 150 mass ppm or lower, and
wherein said gallium nitride-based monocrystalline grains have oxygen concentrations measured by a dynamic SIMS method of 2×10¹⁷ cm⁻³ or higher.

2. The sputtering target of claim 1, wherein said gallium nitride-based crystalline body has a relative density of 98.0% or higher measured by Archimedes method.

3. The sputtering target of claim 1, wherein said gallium nitride-based crystalline body has a half value width of (002) plane reflection of an X-ray rocking curve of 1000 seconds or lower.

4. The sputtering target of claim 1, having a thickness of 1 mm or larger.

5. The sputtering target of claim 1, having a diameter of 50 mm or larger.

6. The sputtering target of claim 1, wherein said gallium nitride-based crystalline body does not have translucent property.

7. The sputtering target of claim 1, wherein said gallium nitride-based monocrystalline grains have carbon concentrations measured by said dynamic SIMS method of 1×10¹⁶ cm⁻³ or lower.

8. The sputtering target of claim 1, wherein said gallium nitride-based monocrystalline grains have germanium concentrations measured by said dynamic SIMS method of 1×10¹⁸ cm⁻³ or higher.
